(19) United States
(12) Patent Application Publication
(10) Pub. No.: US 2023/0395578 A1
(43) Pub. Date: Dec. 7, 2023

(54) MEMORY PACKAGE ON EXTENDED BASE DIE OVER SOC DIE FOR PACKAGE LAYER COUNT AND FORM FACTOR REDUCTION

(71) Applicant: Intel Corporation, Santa Clara, CA (US)

(72) Inventors: Min Suet LIM, Gelugor (MY); Kavitha NAGARAJAN, Bangalore (IN); Eng Huat GOH, Ayer Itam (MY); Telesphor KAMGAING, Chandler, AZ (US); Chee Kheong YOON, Bayan Lepas (MY); Jooi Wah WONG, Bukit Mertajam (MY); Chu Aun LIM, Hillsboro, OR (US)

(21) Appl. No.: 17/833,600

(22) Filed: Jun. 6, 2022

(51) Int. Cl. H01L 25/10; H01L 25/065; H01L 23/538

(52) U.S. Cl. CPC H01L 25/105; H01L 25/0657; H01L 23/5383; H01L 23/5386; H01L 23/5389; H01L 2225/06562; H01L 2225/06586; H01L 2225/1058; H01L 2225/1035

(57) ABSTRACT

Embodiments disclosed herein include electronic packages. In an embodiment, an electronic package comprises a package substrate, and a base coupled to the package substrate. In an embodiment, a die is coupled to the base, and a memory die module is over the die. In an embodiment, the memory die module is communicatively coupled to the die through routing provided on the base

### TECHNICAL FIELD

Embodiments of the present disclosure relate to electronic packages, and more particularly to packaging architectures that include a memory package above an SoC die with memory routing in an underlying base die or an underlying mold layer.

### BACKGROUND

Typically, memory modules are placed side-by-side with the CPU die. The memory routings from the CPU die occupies at least five routing layers (two DDR IO layers sandwiched with three ground layers for referencing). This implementation requires a ten layer package and takes up significant package XY area. Current package routing also requires long route lengths in the package (e.g., 20 mm or longer). This negatively impacts signal integrity, which impacts memory speed. Additionally, DDR physical layer (Phy) occupies a long die shoreline, which limits die size reductions.

Other solutions have also been investigated. One solution includes placing the memory chiplets on the die or using a package on package (POP) architecture. However, memory chiplets stacked on the SoC die requires through silicon vias (TSVs) through the SoC die and requires a redesign of the memory die module. It also makes the assembly flow more complex. For example, current memory die in a DRAM package are wire bonded to the substrate. In the case of a POP architecture, there is still the need for routing the memory signals through the underlying base package substrate. As such, it is not possible to reduce the layers of the base package substrate.

### BRIEF DESCRIPTION OF THE DRAWINGS

FIG. 1A is a plan view illustration of an electronic package with a memory die module coupled to a system on a chip (SoC) in a side-by-side architecture.

FIG. 1B is a cross-sectional illustration of the electronic package in FIG. 1A.

FIG. 1C is a plan view illustration of an electronic package with a memory die module over the SoC with through silicon vias (TSVs).

FIG. 1D is a cross-sectional illustration of the electronic package in FIG. 1C.

FIG. 1E is a plan view illustration of an electronic package with a memory die module configured in a package-on-package (PoP) configuration with the SoC.

FIG. 1F is a cross-sectional illustration of the electronic package in FIG. 1E, in accordance with an embodiment.

FIG. 2A is a plan view illustration of an electronic package with a base die under the SoC that includes pads for receiving a memory die module, in accordance with an embodiment.

FIG. 2B is a cross-sectional illustration of the electronic package in FIG. 2A, in accordance with an embodiment.

FIG. 3A is a plan view illustration of an electronic package with a memory die module over an SoC, in accordance with an embodiment.

FIG. 3B is a cross-sectional illustration of the electronic package in FIG. 3A along line B-B′, in accordance with an embodiment.

FIG. 3C is a cross-sectional illustration of the electronic package in FIG. 3A along line C-C′, in accordance with an embodiment.

FIG. 4 is a cross-sectional illustration of an electronic package with a memory die module over a die with a connection from the memory die module to the die made through a mold layer, in accordance with an embodiment.

FIG. 5A is a cross-sectional illustration of a carrier, in accordance with an embodiment.

FIG. 5B is a cross-sectional illustration of the carrier after vias are formed on the carrier, in accordance with an embodiment.

FIG. 5C is a cross-sectional illustration of the carrier after a bridge is attached to the carrier, in accordance with an embodiment.

FIG. 5D is a cross-sectional illustration of the carrier after a mold layer is formed around the vias and the bridge, in accordance with an embodiment.

FIG. 5E is a cross-sectional illustration of the mold layer after a redistribution layer is provided over the mold layer, in accordance with an embodiment.

FIG. 5F is a cross-sectional illustration of the mold layer after dies are coupled to the bridge, in accordance with an embodiment.

FIG. 5G is a cross-sectional illustration of the mold layer after a second mold layer is provided around the dies, in accordance with an embodiment.

FIG. 5H is a cross-sectional illustration of the mold layer after the carrier is removed, in accordance with an embodiment.

FIG. 5I is a cross-sectional illustration after a second redistribution layer is formed on a bottom of the mold layer, in accordance with an embodiment.

FIG. 5J is a cross-sectional illustration of the mold layer after the second mold layer around the dies is planarized, in accordance with an embodiment.

FIG. 5K is a cross-sectional illustration of an electronic package after a memory die module is attached to the mold layer over the dies, in accordance with an embodiment.

FIG. 6 is a cross-sectional illustration of an electronic system with a memory die module above the dies and coupled to the dies through a mold layer, in accordance with an embodiment.

FIG. 7 is a cross-sectional illustration of an electronic system with a memory die module over an SoC and coupled to the SoC through a base, in accordance with an embodiment.

FIG. 8 is a schematic of a computing device built in accordance with an embodiment.

### EMBODIMENTS OF THE PRESENT DISCLOSURE

Described herein are packaging architectures that include a memory package above an SoC die with memory routing in an underlying base die or an underlying mold layer, in accordance with various embodiments. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

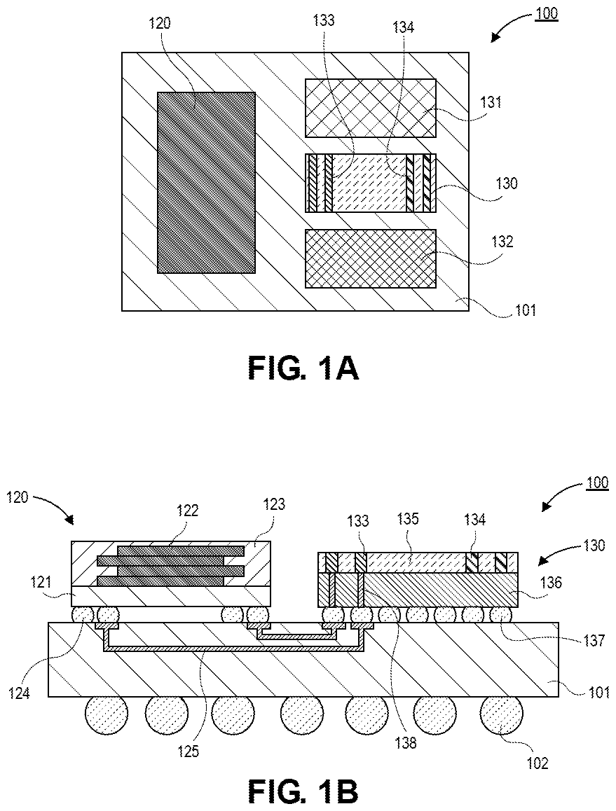

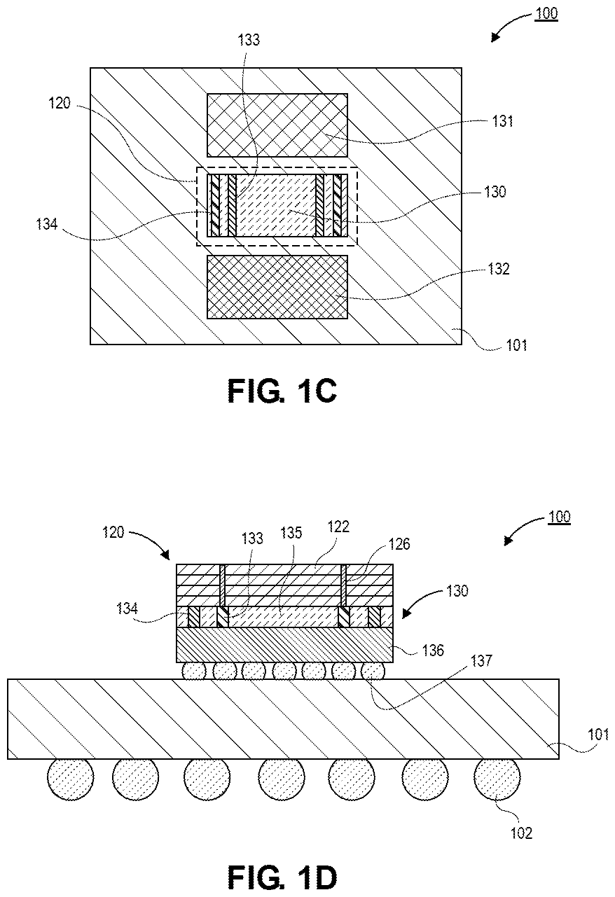

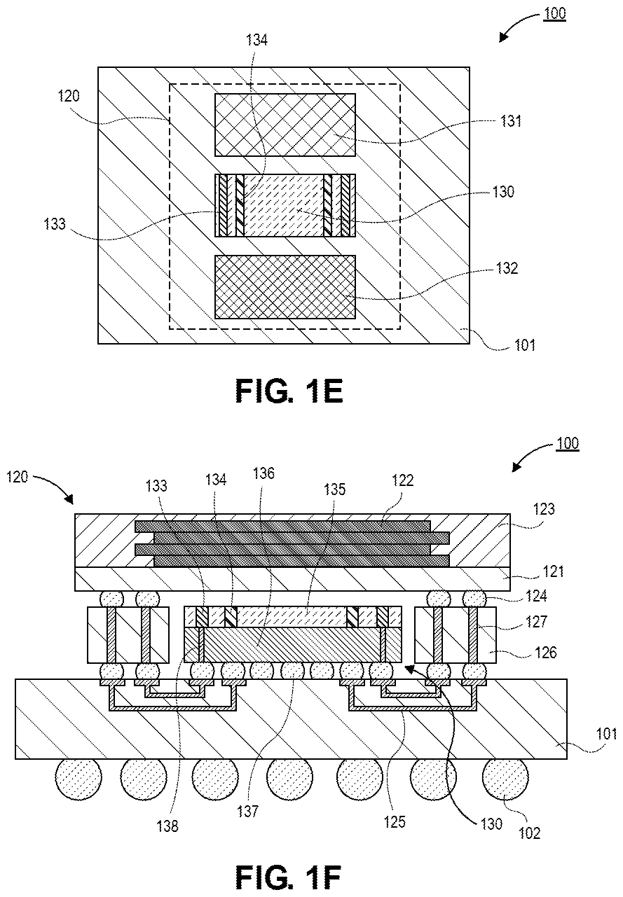

Referring now to FIGS. 1A-1F, a series of illustrations depicting some memory on package architectures is shown. In FIG. 1A, the electronic package 100 includes a memory die module 120 that is provided adjacent to an SoC 130 on a package substrate 101. Additional dies 131 and 132 may also be provided on the package substrate 101. In the SoC, the memory physical layer (phy) 133 is located on an edge of the SoC 130 closest to the memory die module 120. The high speed I/O (HSIO) phy 134 is located on the opposite side of the SoC 130. FIG. 1B is a cross-section of the electronic package 100 in FIG. 1A. As shown, the memory die module 120 may include a package substrate 121, a stack of memory dies 122, and a mold layer 123 around the memory dies 122. Interconnects 124 may couple the memory die module 120 to the package substrate 101. As shown, routing 125 through the package substrate 101 couples the memory die module 120 to the SoC 130. Interconnects 137 may couple the SoC 130 to the package substrate 101. The SoC 130 may include a base 136, a high speed I/O (HSIO) phy 134, and a die 135. Vias 138 through the base 136 may couple the routing 125 to the memory phy 133. Interconnects 102 may be on a bottom of the package substrate 101.

Such an architecture has several drawbacks. One issue is that placing the memory die module 120 adjacent to the SoC 130 results in an increase in the XY form factor of the electronic package. Further, the length of the routing 125 can be significantly long (e.g., 20 mm or greater). This results in signal integrity issues. Additionally, further scaling of the SoC 130 may be limited since the die 135 is shoreline limited. Routing 125 through the package substrate 101 also increases the layer count of the package substrate 101 and increases cost.

To combat some of those issues, it may be possible to arrange the memory die module 120 so that it is provided over the top surface of the SoC 130. An example of such an architecture is shown in FIG. 1C. As indicated by the dashed box, the memory die module 120 may be provided over a top surface of the SoC 130. Providing the memory die module 120 over the SoC 130 allows for the HSIO phy 134 to be on the outside edges of the SoC 130. As shown in the cross-section in FIG. 1D, the die module 120 includes a stack of memory dies 122 may include through silicon vias (TSVs) 126 that couple the memory dies 122 to the memory PHY 133. TSVs (not shown) may also be needed through the die 135. However, the inclusion of TSVs 126 significantly changes the structure of the memory die module 120, and the memory die module 120 will need to be redesigned. TSVs 126 also increase the cost of the memory die module 120 compared to existing solutions that include wire bonded architectures.

A package-on-package (PoP) architecture allows for the use of existing memory die modules 120. An example of such a PoP architecture is shown in FIG. 1E. As shown, the memory die module 120 covers all of the dies 130-132 in some instances. As illustrated in FIG. 1F, the memory die module 120 is coupled to the package substrate 101 through the use of an interposer 126. The interposer 126 may be an organic material with vias 127 in order to extend the coupling back down to the package substrate 101. Routing 125 in the package substrate 101 couples the memory die module 120 to the SoC 130. However, such an architecture still requires routing through the package substrate 101. As such, the layer count of the package substrate 101 cannot be reduced (e.g., from a ten layer package substrate).

As noted above, SoC architectures with companion memory die modules currently have a large form factor since the memory die modules are placed adjacent to the SoC die. Attempts to move the memory die modules to above the SoC die have helped reduced the XY form factor of the system, but are limited by complex design and still may not decrease the layer count of the underlying package substrate.

Accordingly, embodiments disclosed herein include memory die module interconnect architectures that are connected to the SoC through either a base die below the SoC or a mold layer below the SoC. Both architectures result in the signal routing from the memory die module to the SoC being implemented above the package substrate. As such, it is possible to reduce the layer count of the underlying package substrate. Additionally, the XY form factors can be reduced since the memory die modules are placed over a top surface of the SoC instead of being adjacent to the SoC. Furthermore, since there is no need for TSV architectures, existing memory die modules may be used in such architectures.

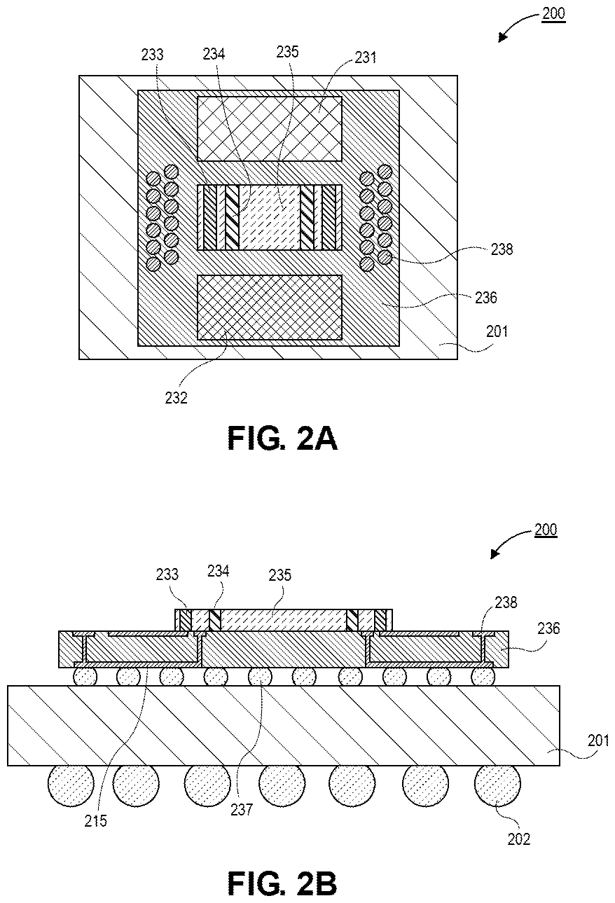

Referring now to FIG. 2A, a plan view illustration of an electronic package 200 is shown, in accordance with an embodiment. In an embodiment, the electronic package 200 may include a package substrate 201. The package substrate 201 may include routing layers and a core. In some embodiments, the package substrate 201 may have ten or fewer routing layers. In a particular embodiment, the package substrate 201 may include six routing layers.

A base 236 may be coupled to the package substrate 201. The base 236 may be an interposer substrate that is used to make connections between overlying structures. The base 236 may comprise silicon in some embodiments. Other embodiments may include a glass base 236, or any other suitable material. In an embodiment, an SoC comprises a die 235 that is provided on the base 236. The die 235 may be a compute die, such as a central processing unit (CPU) or the like. Additional dies 231 and 232 may also be provided over a top surface of the base 236. The additional dies 231 may include graphics processing units (GPUs), power regulation dies, or any other type of die useful in an SoC architecture. As shown, the architecture described herein allows for the memory phys 233 to be placed on the outside edges of the die 235. The HSIO phys 234 may be located between the memory phys 233. In an embodiment, the base 236 may also include pads 238. The pads 238 are positioned adjacent to edges of the die 235 that include the memory phys 233. For example, in FIG. 2A, a first group of pads 238 are on the left of the die 235 and a second group of pads 238 are on the right of the die 235.

As used herein, an SoC architecture may include various die architectures that include one or more dies. In one example, a die may be provided over a base, such as base 236. The base may be used to provide connections between various dies (e.g., dies 235, 231, and 232). In other embodiments, an SoC may include a stacked die architecture. SoC devices may comprise a CPU die, a graphics die, or any other SoC architecture. In some instances, the SoC devices may also be considered a platform control die (PCD).

Referring now to FIG. 2B, a cross-sectional illustration of the electronic package 200 in FIG. 2A is shown, in accordance with an embodiment. As shown, the routing 215 between the pads 238 and the die 235 are provided in the base 236. In some embodiments, the routing 215 may be directly on (or in) the base 236. In other embodiments, the routing 215 may be provided on redistribution layers (not shown) formed over the top and/or bottom surface of the base 236.

In the illustrated embodiment, the die 235 is shown as being directly on the base 236. It is to be appreciated that an interconnect (e.g., solder, copper pads, etc.) may be provided between the base 236 and the die 235. In an embodiment, the base 236 may be coupled to the package substrate 201 by interconnects 237, such as solder balls or the like. Interconnects 202 may be provided on the bottom of the package substrate 201 (e.g., for connecting to a board).

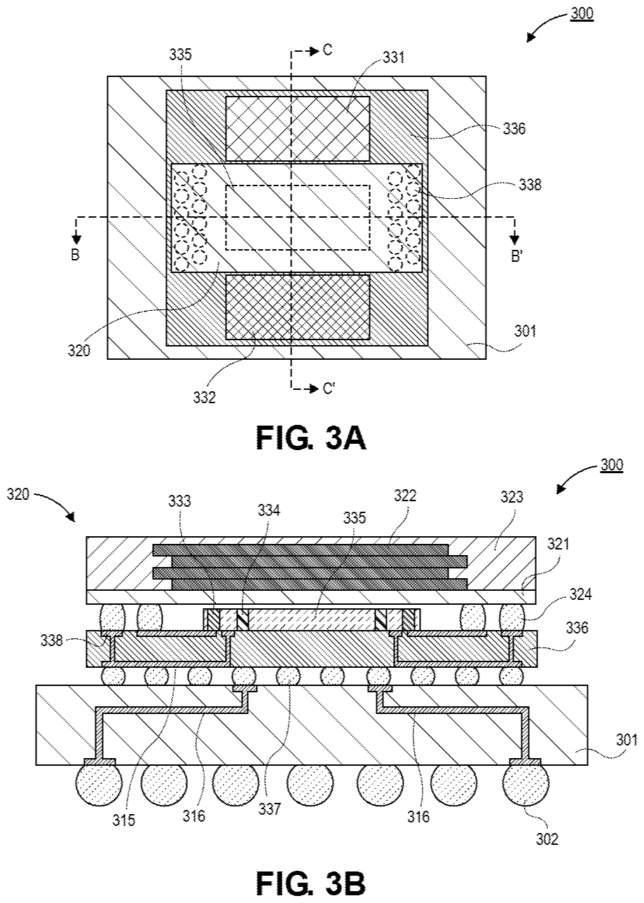

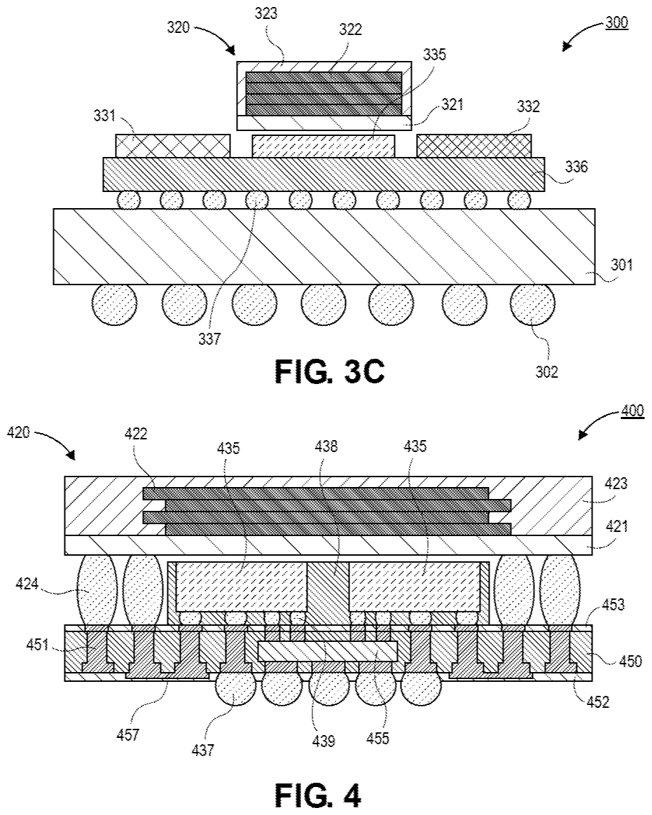

Referring now to FIG. 3A, a plan view illustration of an electronic package 300 with a memory die module 320 attached is shown, in accordance with an embodiment. The components underlying the memory die module 320 may be substantially similar to those described above with respect to FIG. 2A. For example, dies 331 and 332 may be provided adjacent to the SoC die 335. The dies 331, 332, and 335 may be provided above the base 336. Pads 338 may also be provided on the base 336. As shown, the memory die module 320 is provided above the SoC die 335 and the pads 338. That is, the SoC die 335 and the pads 338 are illustrated with dashed lines. In FIG. 3A, only the package substrate 321 of the die module 320 is shown in order to not obscure the Figure.

Referring now to FIG. 3B, a cross-sectional illustration of the electronic package 300 in FIG. 3A along line B-B′ is shown, in accordance with an embodiment. As shown, the electronic package 300 includes a memory die module 320 that is provided over a top surface of the SoC die 335. As used herein, a “memory die module” includes one or more memory dies. The memory dies may be any type of memory architecture. For example, the memory dies may include DRAM memory, or any other type (or types) of memory. In the particular embodiment shown in FIG. 3B, the memory die module 320 includes a package substrate 321 and a plurality of memory dies 322 in a stack over the package substrate 321. For example, four memory dies 322 are illustrated in FIG. 3B. In an embodiment, the memory dies 322 may be offset from each other. The offset structure allows for the top surface of each of the memory dies 322 to be accessible in order to attach wire bonds (not shown) between the memory dies 322 and the package substrate 321. A mold layer 323 may be provided around the memory dies 322. As used herein, “around” or “over and around” may each refer to being around a perimeter and over a top surface. For example, “around” or “over and around” may include a layer that embeds another structure. That is, the memory dies 322 may be embedded in the mold layer 323.

In an embodiment, the package substrate 321 of the die module 320 may be coupled to the pads 338 on the base 336. For example, solder balls 324 or the like may be used to couple the die module 320 to the base 336. In an embodiment, the pads 338 may be communicatively coupled to the SoC die 335 by routing 315 on and/or in the base 336. For example, the routing 315 may be included on redistribution layers (not shown) formed over and/or under the base 336.

The base 336 may be coupled to the package substrate 301 by interconnects 337, such as solder balls or the like. As shown, routing 316 may be provided in the package substrate 301. The routing 316 may include break out routing for the HSIO phy 334. Since the routing for the memory phy 333 is provided in the base 336, the routing 316 for the HSIO phy 334 can break out in all directions. As such, the SoC die 335 is no longer shoreline limited and allows for further scaling of the SoC die 335. Interconnects 302 may be provided on the bottom of the package substrate 301.

Referring now to FIG. 3C, a cross-sectional illustration of the electronic package 300 in FIG. 3A along line C-C′ is shown, in accordance with an embodiment. As shown, the memory die module 320 is provided above the SoC die 335. The other dies 331 may be adjacent to the SoC die 335. Also, the memory die module 320 may be provided over only the SoC die 335. In other embodiments, the memory die module 320 may extend over the other dies 331 and 332. In the illustrated embodiment, the memory die module 320 is depicted as floating above the SoC die 335. However, it is to be appreciated that the SoC die 335 is supported from below by the pads 338 (as shown in FIG. 3B).

Referring now to FIG. 4, a cross-sectional illustration of an electronic package 400 is shown, in accordance with an additional embodiment. In an embodiment, the electronic package 400 may include a mold layer 450. The mold layer 450 may include an epoxy material or any other suitable material for molding. The mold layer 450 may include one or more redistribution layers 452 and 453. While redistribution layers 452 and 453 are provided over both horizontal surfaces of the mold layer 450, it is to be appreciated that redistribution layers may be provided over one (or none) of the horizontal surfaces of the mold layer 450. The mold layer may include vias 451 that pass through a thickness of the mold layer 450. Additionally, a bridge 455 or the like may be included in the mold layer 450. In an embodiment, the bridge 455 may be used to communicatively couple together dies 435 positioned above the mold layer 450. For example, the dies 435 may be coupled to the mold layer 450 and the bridge 455 through interconnects 439. The dies 435 may be embedded in a second mold layer 438. The dies 435 may be SoC dies or other compute die architectures.

In an embodiment, a memory die module 420 may be provided above the dies 435. For example, the memory die module 420 may be coupled to the mold layer 450 through interconnects 424, such as solder interconnects or the like. In a particular embodiment, the memory die module 420 is coupled to the dies 435 through routing 457 on the mold layer 450. For example, the routing 457 may be implemented on redistribution layers 453 and/or 452. As such, the routing from the memory die module 420 to the dies 435 does not need to pass through an underlying package substrate or board (not shown in FIG. 4).

In an embodiment, the memory die module 420 may include a memory package substrate 421. A stack of one or more memory dies 422 may be provided over the memory package substrate 421. In a particular embodiment, the memory dies 422 are offset from each other to enable wire bonding (not shown) to the package substrate 421. A mold layer 423 may be provided around the memory dies 422. Interconnects 437 may be provided under the mold layer 450.

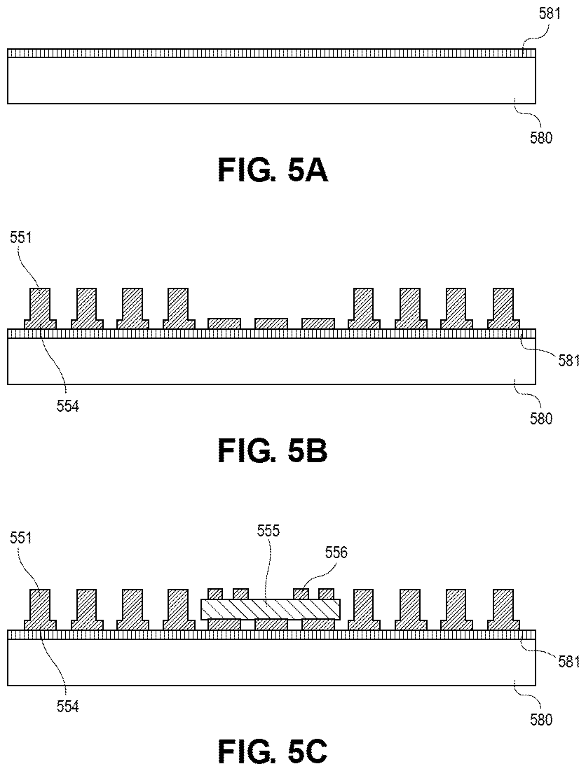

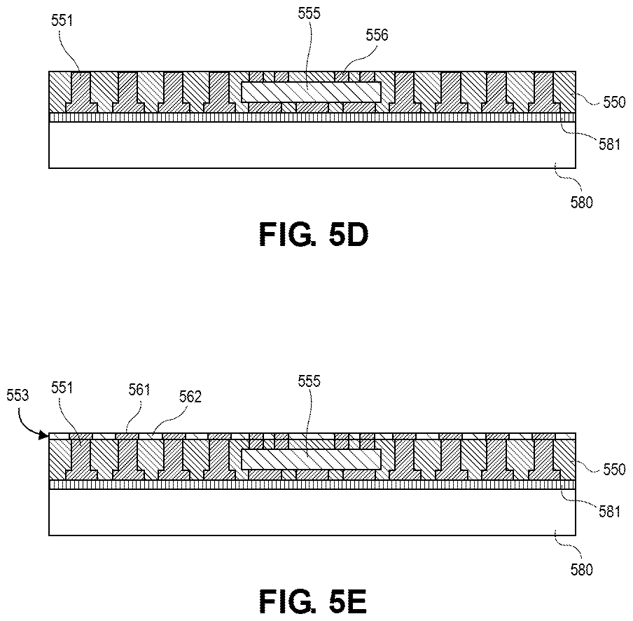

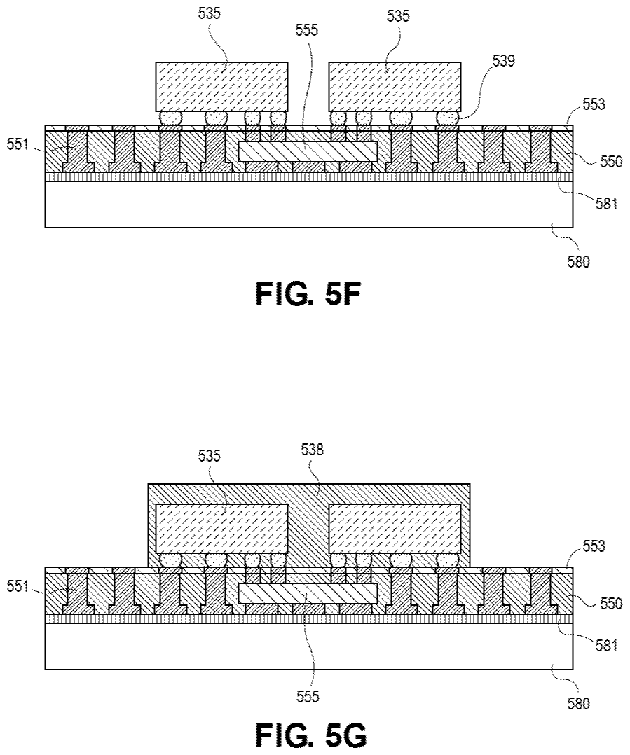

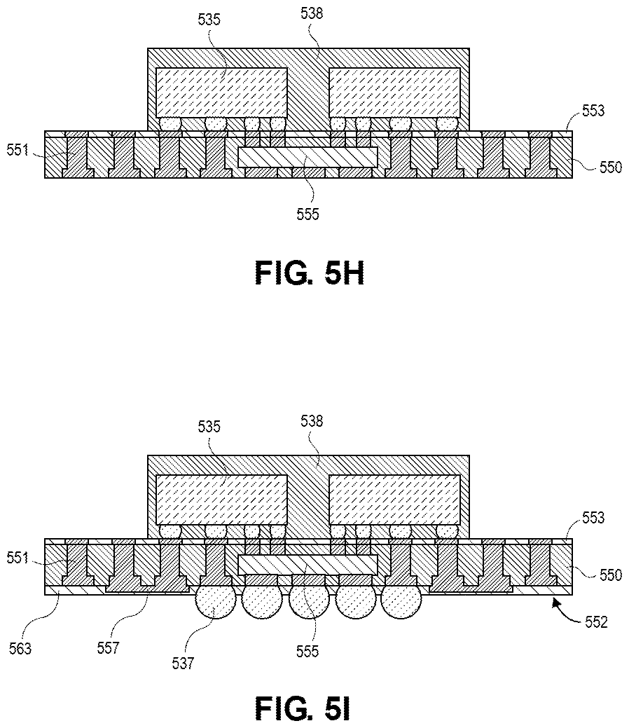

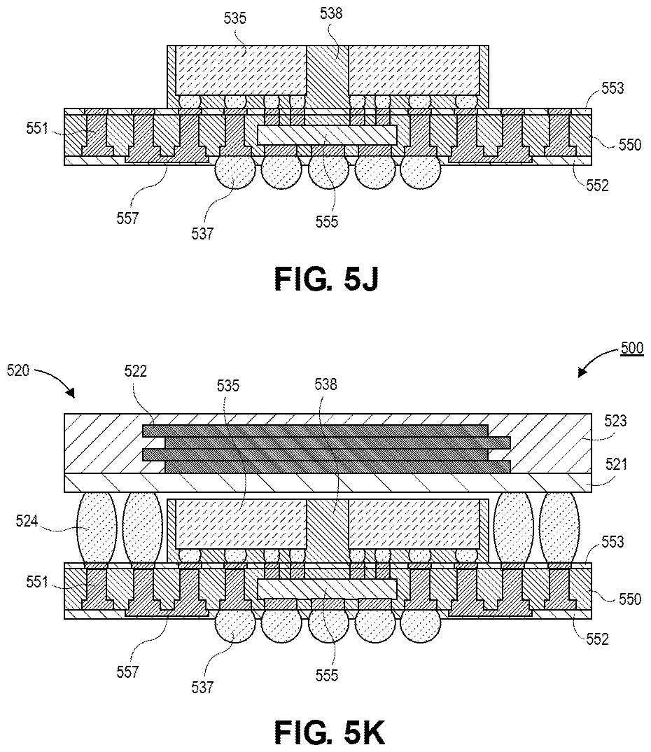

Referring now to FIGS. 5A-5K, a series of illustrations depicting a process for forming an electronic package similar to the electronic package 400 in FIG. 4 is shown, in accordance with an embodiment.

Referring now to FIG. 5A, a cross-sectional illustration of a carrier 580 is shown, in accordance with an embodiment. In an embodiment, the carrier 580 may be any suitable rigid material. For example, the carrier 580 may comprise glass, silicon, or the like. In an embodiment, a releasable bonding film 581 may be provided over the carrier 580.

Referring now to FIG. 5B, a cross-sectional illustration of the carrier 580 after pads 554 and vias 551 are formed is shown, in accordance with an embodiment. The pads 554 and vias 551 may be formed with any suitable processing operations. For example, a seed layer may be provided over the bonding film 581. Plating for the pads 554 and vias 551 may be implemented using suitable patterning materials, such as a dry film resist (DFR) or the like. After the pads 554 and vias 551 are formed, the DFR may be stripped and the seed layer may be removed to provide a structure similar to the structure shown in FIG. 5B.

Referring now to FIG. 5C, a cross-sectional illustration of the carrier 580 after a bridge 555 is attached to pads 554 is shown, in accordance with an embodiment. In an embodiment, pads 556 may be provided on a top side of the bridge 555 in order to couple with overlying dies (added in a subsequent processing operation). The bridge 555 may include vias (not shown) in order to couple together the top and bottom surfaces of the bridge 555.

Referring now to FIG. 5D, a cross-sectional illustration of the carrier 580 after a mold layer 550 is provided around the vias 551 and the bridge 555 is shown, in accordance with an embodiment. That is, the mold layer 550 may embed the vias 551 and the bridge 555. In an embodiment, the mold layer 550 may be recessed (e.g., with a grinding process) in order to expose top surfaces of the vias 551 and the pads 556.

Referring now to FIG. 5E, a cross-sectional illustration of the carrier 580 after a redistribution layer 553 is formed over the mold layer 550 is shown, in accordance with an embodiment. In an embodiment, the redistribution layer 553 may include dielectric material 562 and conductive pads 561, routing, or the like. In some instances, the redistribution layer 553 may be considered a reset layer in order to bring the underlying features into a proper alignment for subsequently added features.

Referring now to FIG. 5F, a cross-sectional illustration of the carrier 580 after dies 535 are attached to the mold layer 550 is shown, in accordance with an embodiment. In an embodiment, the dies 535 may be attached with interconnects 539. The interconnects 539 are shown as solder bumps, but it is to be appreciated that any interconnect architecture (e.g., copper bumps, hybrid bonding, or the like) may be used to connect the dies 535 to the mold layer 550. The interconnects 539 may couple the dies 535 to the bridge 555 and the vias 551. In some embodiments, an underfill (not shown) may also be provided around the interconnects 539.

Referring now to FIG. 5G, a cross-sectional illustration of the carrier 580 after a second mold layer 538 is provided over the dies 535 is shown, in accordance with an embodiment. The molding process may be a selective molding process. That is, the second mold layer 538 may be selectively deposited around the dies 535. For example, a pair of vias 551 on each side of the second mold layer 538 may remain uncovered. The uncovered vias 551 may be used to attach the memory die module in a subsequent processing operation.

Referring now to FIG. 5H, a cross-sectional illustration of the mold layer 550 after the carrier 580 is removed is shown, in accordance with an embodiment. In an embodiment, the carrier 580 may be removed by debonding the bonding layer 581. For example, a UV exposure or application of heat may be used to release the bonding layer 581. The bottom of the mold layer 550 may then be cleaned in some embodiments.

Referring now to FIG. 5I, a cross-sectional illustration of the mold layer 550 after a backside redistribution layer 552 is formed is shown, in accordance with an embodiment. As shown, the backside redistribution layer 552 may include a dielectric layer 563 and routing 557. The routing 557 may electrically couple the outside vias 551 to the vias 551 below the dies 535. In an embodiment, interconnects 537 may also be plated. For example, the interconnects 537 may include solder balls or the like.

Referring now to FIG. 5J, a cross-sectional illustration of the mold layer 550 after the second mold layer 538 is recessed is shown, in accordance with an embodiment. The second mold layer 538 may be recessed with a grinding process. The recessing of the second mold layer 538 may result in the backside surfaces of the dies 535 being exposed. The recessing may also decrease a thickness of the dies 535 in some embodiments.

Referring now to FIG. 5K, a cross-sectional illustration of the electronic package 500 after the memory die module 520 is attached is shown, in accordance with an embodiment. The memory die module 520 may be coupled to the exposed vias 551 by interconnects 524, such as solder balls or the like. In an embodiment, the memory die module 520 is coupled to the dies 535 through the vias 551, and the routing 557. Particularly, there is no need to route signals between the memory die module 520 and the dies 535 through an underlying package substrate (not shown).

In an embodiment, the memory die module 520 may include a package substrate 521 and a stack of one or more memory dies 522 over the package substrate 521. The memory dies 522 may be coupled to the package substrate 521 through wire bonds (not shown). In an embodiment, a mold layer 523 may be provided over the memory dies 522.

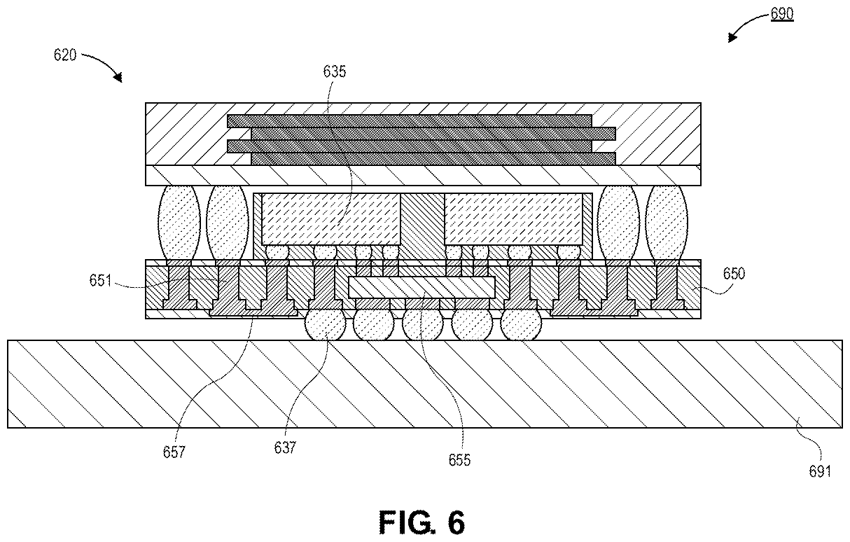

Referring now to FIG. 6, a cross-sectional illustration of an electronic system 690 is shown, in accordance with an embodiment. In an embodiment, the electronic system 690 may include a mold layer 650 with vias 651 and a bridge 655. The bridge 655 may couple together two dies 635 above the mold layer 650. Routing 657 on the mold layer 650 (e.g., directly on the mold layer 650 or in a redistribution layer over the mold layer 650) may couple the memory die module 620 to the dies 635. In an embodiment, the mold layer 650 may be coupled to an underlying substrate 691 by interconnects 637. In some embodiments, the substrate 691 may be a package substrate. In other embodiments, the substrate 691 may be a board (e.g., a PCB). Due to the routing 657 on the mold layer 650, there is no need for signals that pass between the memory die module 620 and the dies 635 to pass over the underlying substrate 691.

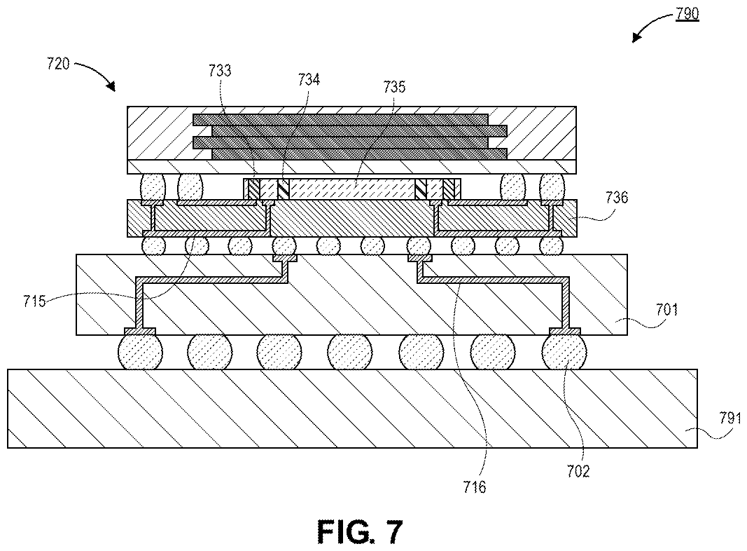

Referring now to FIG. 7, a cross-sectional illustration of an electronic system 790 is shown, in accordance with an embodiment. As shown, the electronic system 790 may include a board 791, such as a PCB. The board 791 may be coupled to a package substrate 701 by interconnects 702. A base 736 may be provided over the package substrate 701. In an embodiment, an SoC die 735 is provided over the base 736. The SoC die 735 may include memory phys 733 at edges of the SoC die 735 and HSIO phys 734 inside the memory phys 733. A memory die module 720 may be provided over the SoC die 735. In an embodiment, a width of the SoC die 735 is smaller than a width of the memory die module 720. The memory die module 720 may be coupled to the SoC die 735 through routing 715 on and/or in the base 736. Providing the routing 715 in the base 736 frees up routing layers and space in the package substrate 701 to provide HSIO routing 716.

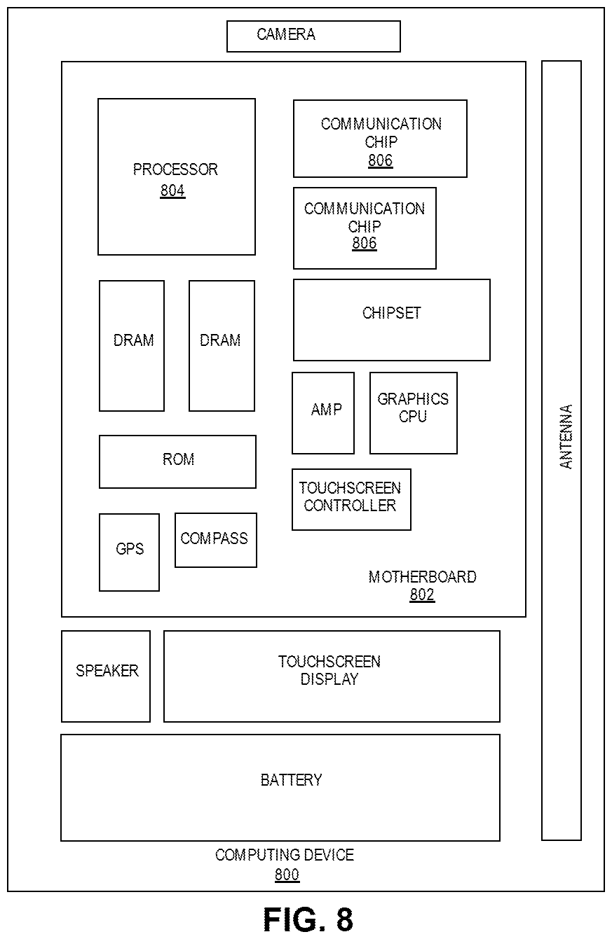

FIG. 8 illustrates a computing device 800 in accordance with one implementation of the invention. The computing device 800 houses a board 802. The board 802 may include a number of components, including but not limited to a processor 804 and at least one communication chip 806. The processor 804 is physically and electrically coupled to the board 802. In some implementations the at least one communication chip 806 is also physically and electrically coupled to the board 802. In further implementations, the communication chip 806 is part of the processor 804.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 806 enables wireless communications for the transfer of data to and from the computing device 800. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 806 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 800 may include a plurality of communication chips 806. For instance, a first communication chip 806 may be dedicated to shorter range wireless communications such as Wi-Fi and Bluetooth and a second communication chip 806 may be dedicated to longer range wireless communications such as GPS, EDGE, GPRS, CDMA, WiMAX, LTE, Ev-DO, and others.

The processor 804 of the computing device 800 includes an integrated circuit die packaged within the processor 804. In some implementations of the invention, the integrated circuit die of the processor may be part of an electronic package that includes a memory die module that is coupled to the integrated circuit die through a base or a mold layer, in accordance with embodiments described herein. The term “processor” may refer to any device or portion of a device that processes electronic data from registers and/or memory to transform that electronic data into other electronic data that may be stored in registers and/or memory.

The communication chip 806 also includes an integrated circuit die packaged within the communication chip 806. In accordance with another implementation of the invention, the integrated circuit die of the communication chip may be part of an electronic package that includes a memory die module that is coupled to the integrated circuit die through a base or a mold layer, in accordance with embodiments described herein.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

Example 1: an electronic package, comprising: a package substrate; a base coupled to the package substrate; a die coupled to the base; and a memory die module over the die, wherein the memory die module is communicatively coupled to the die through routing provided on the base.

Example 2: the electronic package of Example 1, wherein the base comprises silicon.

Example 3: the electronic package of Example 1 or Example 2, wherein one or more redistribution layers are provided on one or both horizontal surfaces of the base.

Example 4: the electronic package of Examples 1-3, wherein a first memory physical layer (phy) is at a first edge of the die and a second memory phy is at a second edge of the die.

Example 5: the electronic package of Example 4, wherein a first high speed I/O (HSIO) phy and a second HSIO phy are located between the first memory phy and the second memory phy.

Example 6: the electronic package of Example 5, wherein the first HSIO phy and the second HSIO phy breakout laterally in opposite directions in the package substrate.

Example 7: the electronic package of Examples 1-6, wherein the communicative coupling between the memory die module and the die does not pass into the package substrate.

Example 8: the electronic package of Examples 1-7, wherein the memory die module comprises: a memory package substrate; a plurality of stacked memory dies; and a mold layer over and around the plurality of stacked memory dies.

Example 9: the electronic package of Examples 1-8, wherein a width of the memory die module is greater than a width of the die.

Example 10: the electronic package of Examples 1-10, wherein the die is a system on a chip (SoC).

Example 11: an electronic package, comprising: a mold layer; a die coupled to the mold layer; and a memory die module above the die and coupled to the mold layer, wherein the memory die module is communicatively coupled to the die through routing provided on the mold layer.

Example 12: the electronic package of Example 11, further comprising: vias through the mold layer.

Example 13: the electronic package of Example 12, wherein one or more redistribution layers are provided on one or both horizontal surfaces of the mold layer.

Example 14: the electronic package of Examples 11-13, wherein a plurality of dies are provided over the mold layer.

Example 15: the electronic package of Example 14, wherein the plurality of dies are communicatively coupled to each other by a bridge embedded in the mold layer.

Example 16: the electronic package of Example 15, wherein the plurality of dies are embedded in a second mold layer.

Example 17: the electronic package of Examples 11-16, wherein the memory die module comprises: a memory package substrate; a plurality of stacked memory dies; and a second mold layer over and around the plurality of stacked memory dies.

Example 18: the electronic package of Examples 11-17, wherein a width of the memory die module is greater than a width of the die.

Example 19: the electronic package of Example 18, wherein the memory die module is coupled to the mold layer by solder balls.

Example 20: the electronic package of Examples 11-19, wherein mold layer is coupled to a package substrate.

Example 21: an electronic package, comprising: a base; a die with a first width coupled to the base; and a memory die module with a second width coupled to the base, wherein the second width is greater than the first width, wherein the die is provided between the base and the memory die, and wherein the memory die module is coupled to the die through routing on the base.

Example 22: the electronic package of Example 21, wherein the base is a mold layer.

Example 23: the electronic package of Example 21, wherein the base comprises silicon.

Example 24: an electronic system, comprising: a board; a package substrate coupled to the board; and a multi-die module coupled to the package substrate, wherein the multi-die module comprises: a base; a die with a first width coupled to the base; and a memory die module with a second width coupled to the base, wherein the second width is greater than the first width, and wherein the memory die module is coupled to the base by vias adjacent to the die.

Example 25: the electronic system of Example 24, wherein the base is a mold layer or the base comprises silicon.

What is claimed is:

1. An electronic package, comprising:
a package substrate;
a base coupled to the package substrate;
a die coupled to the base; and
a memory die module over the die, wherein the memory die module is communicatively coupled to the die through routing provided on the base.

2. The electronic package of claim 1, wherein the base comprises silicon.

3. The electronic package of claim 1, wherein one or more redistribution layers are provided on one or both horizontal surfaces of the base.

4. The electronic package of claim 1, wherein a first memory physical layer (phy) is at a first edge of the die and a second memory phy is at a second edge of the die.

5. The electronic package of claim 4, wherein a first high speed I/O (HSIO) phy and a second HSIO phy are located between the first memory phy and the second memory phy.

6. The electronic package of claim 5, wherein the first HSIO phy and the second HSIO phy breakout laterally in opposite directions in the package substrate.

7. The electronic package of claim 1, wherein the communicative coupling between the memory die module and the die does not pass into the package substrate.

8. The electronic package of claim 1, wherein the memory die module comprises:
a memory package substrate;
a plurality of stacked memory dies; and
a mold layer over and around the plurality of stacked memory dies.

9. The electronic package of claim 1, wherein a width of the memory die module is greater than a width of the die.

10. The electronic package of claim 1, wherein the die is a system on a chip (SoC).

11. An electronic package, comprising:
a mold layer;
a die coupled to the mold layer; and
a memory die module above the die and coupled to the mold layer, wherein the memory die module is communicatively coupled to the die through routing provided on the mold layer.

12. The electronic package of claim 11, further comprising:
vias through the mold layer.

13. The electronic package of claim 12, wherein one or more redistribution layers are provided on one or both horizontal surfaces of the mold layer.

14. The electronic package of claim 11, wherein a plurality of dies are provided over the mold layer.

15. The electronic package of claim 14, wherein the plurality of dies are communicatively coupled to each other by a bridge embedded in the mold layer.

16. The electronic package of claim 15, wherein the plurality of dies are embedded in a second mold layer.

17. The electronic package of claim 11, wherein the memory die module comprises:
a memory package substrate;
a plurality of stacked memory dies; and
a second mold layer over and around the plurality of stacked memory dies.

18. The electronic package of claim 11, wherein a width of the memory die module is greater than a width of the die.

19. The electronic package of claim 18, wherein the memory die module is coupled to the mold layer by solder balls.

20. The electronic package of claim 11, wherein mold layer is coupled to a package substrate.

21. An electronic package, comprising:
a base;
a die with a first width coupled to the base; and
a memory die module with a second width coupled to the base, wherein the second width is greater than the first width, wherein the die is provided between the base and the memory die, and wherein the memory die module is coupled to the die through routing on the base.

22. The electronic package of claim 21, wherein the base is a mold layer.

23. The electronic package of claim 21, wherein the base comprises silicon.

24. An electronic system, comprising:
a board;
a package substrate coupled to the board; and
a multi-die module coupled to the package substrate, wherein the multi-die module comprises:
a base;
a die with a first width coupled to the base; and
a memory die module with a second width coupled to the base, wherein the second width is greater than the first width, and wherein the memory die module is coupled to the base by vias adjacent to the die.

25. The electronic system of claim 24, wherein the base is a mold layer or the base comprises silicon.
